(19) United States
(12) Patent Application Publication
(10) Pub. No.: US 2026/0068154 A1
(43) Pub. Date: Mar. 5, 2026

(54) SEMICONDUCTOR MEMORY DEVICE AND METHOD OF OPERATING THE SAME

(71) Applicant: Samsung Electronics Co., Ltd., Suwon-si (KR)

(72) Inventors: Seongil KIM, Suwon-si (KR); Sang-Yong PARK, Suwon-si (KR); Soo Jin KIM, Suwon-si (KR); Younghwi YANG, Suwon-si (KR); Seung Jae BAIK, Suwon-si (KR)

(21) Appl. No.: 19/095,263

(22) Filed: Mar. 31, 2025

(30) Foreign Application Priority Data
Aug. 29, 2024 (KR) 10-2024-0117181

(51) Int. Cl. H10B 41/27; G11C 16/04; G11C 16/26; H01L 23/00; H01L 25/18; H10B 41/10; H10B 41/35; H10B 41/41; H10B 43/10; H10B 43/27; H10B 43/35; H10B 43/40; H10B 80/00; H10D 80/30

(52) U.S. Cl. CPC H10B 41/27; G11C 16/0483; G11C 16/26; H10B 41/10; H10B 41/35; H10B 41/41; H10B 43/10; H10B 43/27; H10B 43/35; H10B 43/40; H10B 80/00; H10D 80/30

(57) ABSTRACT

A semiconductor memory device includes a mold structure including a plurality of gate electrodes stacked in a first direction perpendicular to a top surface of a substrate and a channel structure penetrating the mold structure, and the channel structure may include a light source configured to emit light, a light detector spaced apart from the light source in the first direction and configured to detect light, and a waveguide, through which the light emitted from the light source passes, disposed between the light source and the light detector.

### CROSS-REFERENCE TO RELATED APPLICATIONS

This application claims the benefit of Korean Patent Application No. 10-2024-0117181, filed on Aug. 29, 2024, in the Korean Intellectual Property Office, the disclosure of which is incorporated herein by reference in its entirety.

### BACKGROUND

### 1. Field of the Invention

Example embodiments relate to a semiconductor memory device and a method of operating the same.

### 2. Description of the Related Art

Based on the demand for semiconductor memory devices that may store high-capacity data in an electronic system, research on manners for increasing the data storage capacity of the semiconductor memory device is being conducted. As one of the manners for increasing the data storage capacity of the semiconductor memory device, a semiconductor memory device including memory cells arranged three-dimensionally instead of memory cells arranged two-dimensionally is suggested.

### SUMMARY

An aspect provides a semiconductor memory device in which power consumption and heat generation are decreased and a method of operating the same.

Another aspect provides a semiconductor memory device in which reliability is enhanced and a method of operating the same.

Example embodiments are not limited to the technical features described above, and other unstated technical features may be made apparent to those skilled in the art from the following description.

According to an aspect, a semiconductor memory device includes a mold structure including a plurality of gate electrodes stacked in a first direction perpendicular to a top surface of a substrate and a channel structure penetrating the mold structure, and the channel structure may include a light source configured to emit light, a light detector spaced apart from the light source in the first direction and configured to detect light, and a waveguide, through which the light emitted from the light source passes, disposed between the light source and the light detector.

According to another aspect, a method of operating a semiconductor memory device includes selecting a target word line among a plurality of word lines that are stacked, applying a read voltage to the target word line, and radiating light inside a channel structure penetrating the plurality of word lines.

According to another aspect, a semiconductor memory device includes a mold structure including a plurality of gate electrodes stacked in a first direction perpendicular to a top surface of a substrate and a channel structure penetrating the mold structure, and the channel structure may include a channel hole penetrating the mold structure, a light emitter configured to emit light within the channel hole, a light detector spaced apart from and facing the light emitter in the first direction and configured to detect light within the channel hole, a waveguide, through which the light emitted from the light emitter passes, disposed between the light emitter and the light detector, a variable resistance layer disposed along an inner sidewall of the channel hole, an electrode layer surrounding the waveguide, and a channel layer disposed between the electrode layer and the variable resistance layer.

Additional aspects of example embodiments will be set forth in part in the description which follows and, in part, will be apparent from the description, or may be learned by practice of the disclosure.

According to example embodiments of the present disclosure, it is possible to decrease power consumption and heat generation in a semiconductor memory device.

According to example embodiments of the present disclosure, it is possible to enhance reliability in a semiconductor memory device.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIG. 1 is an example block diagram illustrating a semiconductor memory device according to some example embodiments;

FIG. 2 is an example circuit diagram illustrating a semiconductor memory device according to some example embodiments;

FIG. 3 is a schematic layout diagram illustrating a semiconductor memory device according to some example embodiments;

FIG. 4 is an example diagram showing a cross-section taken along line A-A of FIG. 3;

FIG. 5 is an example diagram illustrating a channel structure of a semiconductor memory device according to some example embodiments;

FIGS. 6 to 10 are diagrams illustrating a method of operating a semiconductor memory device according to some example embodiments;

FIG. 11 is an example diagram illustrating a semiconductor memory device according to some other example embodiments;

FIG. 12 is an example diagram illustrating an electronic system including a semiconductor memory device according to some example embodiments;

FIG. 13 is an example perspective view illustrating an electronic system including a semiconductor memory device according to some example embodiments; and

FIG. 14 is an example diagram showing a cross-section taken along line I-I of FIG. 13.

### DETAILED DESCRIPTION

The words and terminologies used in the specification and claims are not to be construed as limited to common or dictionary meanings but construed as meanings and conceptions coinciding with the technical spirit of the present disclosure. It should be understood that there may be various equivalents and modifications that may replace the specific embodiment described herein.

In the descriptions below, items described in the singular may be applied to a plurality of such items, unless apparently otherwise defined by context. It should be understood that terms such as “comprise or include” are intended to indicate the presence of a feature, a number, a step, an operation, an element, a component, or a combination thereof which are described in the specification and not intended to previously exclude the possibility of the presence or addition of one or more other features, numbers, steps, operations, elements, components, or combinations thereof.

In addition, expressions such as upper side, upper portion, lower side, lower portion, side surface, front surface, and rear surface hereinafter are represented based on a direction illustrated in a drawing and may be represented otherwise when the direction of a corresponding object changes. The shape or size of elements in drawings may be exaggerated for clearer description.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Also these spatially relative terms such as “above” and “below” as used herein have their ordinary broad meanings—for example element A can be above element B even if when looking down on the two elements there is no overlap between them (just as something in the sky is generally above something on the ground, even if it is not directly above).

Unless the context indicates otherwise, an item, layer, or portion of an item or layer described as “extending” or extending “lengthwise” in a particular direction has a length in the particular direction and a width perpendicular to that direction, where the length is greater than the width.

Hereinafter, example embodiments of the present disclosure will be described with reference to the accompanying drawings.

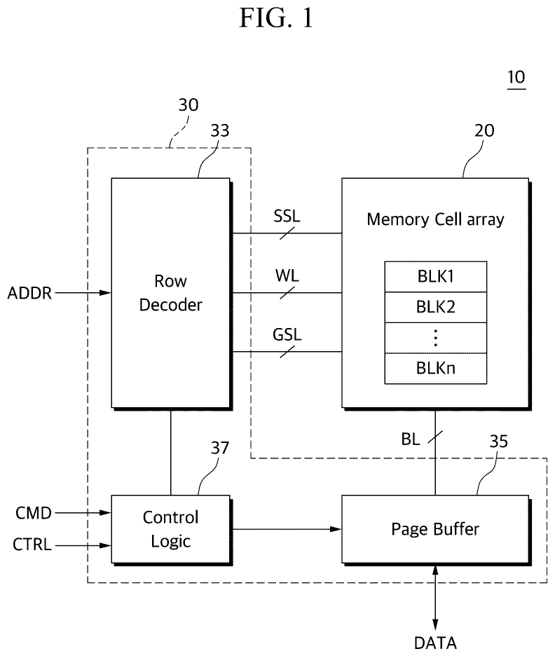

FIG. 1 is an example block diagram illustrating a semiconductor memory device according to some example embodiments.

Referring to FIG. 1, a semiconductor memory device 10 according to some example embodiments may include a memory cell array 20 and a peripheral circuit 30. The semiconductor memory device 10 may be a semiconductor chip including an integrated circuit formed on a die from a wafer, may include a stack of such semiconductor chips, or may include a semiconductor package including one or more semiconductor chips formed on a package substrate and covered with an encapsulant.

According to some example embodiments, the memory cell array 20 may include a plurality of memory cell blocks BLK1 to BLKn. Each of the memory cell blocks BLK1 to BLKn may include a plurality of memory cells. The memory cell array 20 may be connected to the peripheral circuit 30 through a bit line BL (e.g., a plurality of bit lines BL), a word line WL (e.g., a plurality of word lines WL), at least one string selection line SSL, and at least one ground selection line GSL. Specifically, the memory cell blocks BLK1 to BLKn may be connected to a row decoder 33 through the word lines WL, the string selection line(s) SSL, and the ground selection line(s) GSL. In addition, the memory cell blocks BLK1 to BLKn may be connected to a page buffer 35 through the bit lines BL.

According to some example embodiments, the peripheral circuit 30 may receive an address ADDR, a command CMD, and a control signal CTRL from outside of the semiconductor memory device 10 and may transmit and receive data DATA to and from a device outside the semiconductor memory device 10. The peripheral circuit 30 may include a control logic 37, the row decoder 33, and the page buffer 35. Although not illustrated, the peripheral circuit 30 may further include various sub-circuits such as an input/output circuit, a voltage generation circuit generating various voltages for operating the semiconductor memory device 10, and an error correction circuit for correcting errors in the data DATA read from the memory cell array 20.

According to some example embodiments, the control logic 37 may be connected to the row decoder 33, the input/output circuit, and the voltage generation circuit. The control logic 37 may control the overall operation of the semiconductor memory device 10. The control logic 37 may generate various internal control signals used within the semiconductor memory device 10 in response to the control signal CTRL. For example, the control logic 37 may regulate a voltage level provided to the word lines WL and the bit lines BL when a memory operation such as a program operation or an erase operation is performed.

According to some example embodiments, the row decoder 33 may select at least one of the plurality of memory cell blocks BLK1 to BLKn in response to the address ADDR and may select at least one word line WL, at least one string selection line SSL, and at least one ground selection line GSL of the selected memory cell block BLK1 to BLKn. In addition, the row decoder 33 may transmit voltage for performing the memory operation to the word line WL of the selected memory cell block BLK1 to BLKn.

According to some example embodiments, the page buffer 35 may be connected to the memory cell array 20 through the bit lines BL. The page buffer 35 may operate as a writer driver or a sense amplifier. Specifically, when the program operation is performed, the page buffer 35 may operate as the writer driver and apply voltage according to the data DATA to be stored in the memory cell array 20 to the bit line(s) BL. Meanwhile, when a read operation is performed, the page buffer 35 may operate as the sense amplifier and sense the data DATA stored in the memory cell array 20.

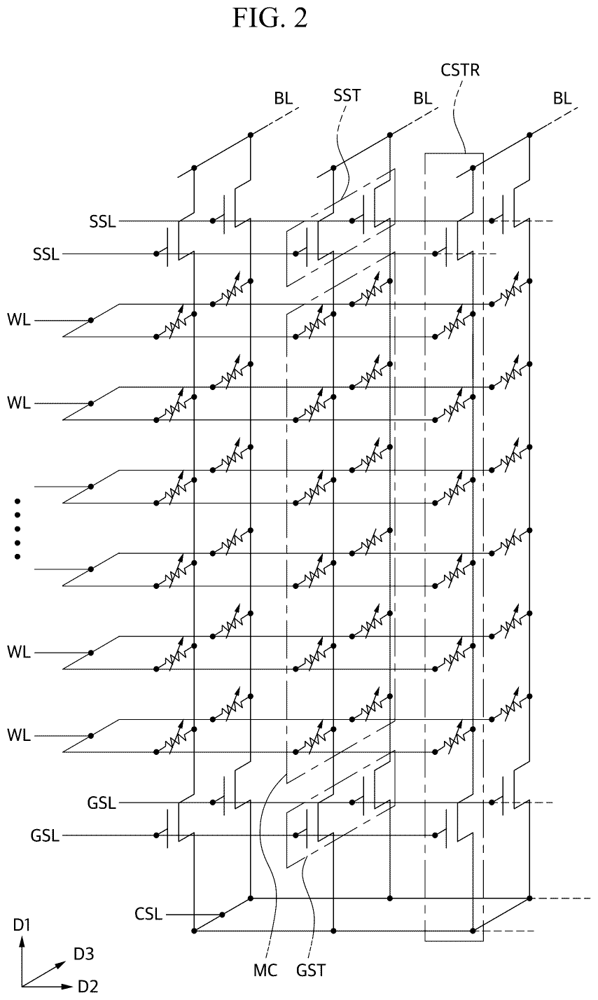

FIG. 2 is an example circuit diagram illustrating a semiconductor memory device according to some example embodiments.

Referring to FIG. 2, a memory cell array (for example, 20 of FIG. 1) of the semiconductor memory device according to some example embodiments may include a common source line CSL, a plurality of bit lines BL, and a plurality of cell strings CSTR.

According to some example embodiments, the common source line CSL may extend in a second direction D2. In some example embodiments, a plurality of common source lines CSL may be arranged two-dimensionally. For example, the plurality of common source lines CSL may be spaced apart from each other and each may extend in the second direction D2. The plurality of common source lines CSL may be spaced apart from each other in a third direction D3. The second direction D2 and third direction D3 may be horizontal directions. An electrically identical voltage may be applied to the common source lines CSL, or different voltages may also be applied thereto, thus being controlled individually.

According to some example embodiments, the plurality of bit lines BL may be arranged two-dimensionally. For example, the bit lines BL may be spaced apart from each other and each may extend in the third direction D3 intersecting the second direction D2. The plurality of cell strings CSTR may be connected in parallel to each of the bit lines BL. The cell strings CSTR may be commonly connected to the common source line CSL. Therefore, the plurality of cell strings CSTR may be disposed between the bit lines BL and the common source line CSL. The cell strings CSTR may extend in a first direction D1. The first direction D1 may be a vertical direction.

According to some example embodiments, each of the cell strings CSTR may include a ground selection transistor GST connected to the common source line CSL, a string selection transistor SST connected to the bit line BL, and a plurality of memory cells MC disposed between the ground selection transistor GST and the string selection transistor SST. Each of the memory cells MC may include a data storage element. The ground selection transistor GST, the string selection transistor SST, and the memory cells MC may be connected in series.

According to some example embodiments, the common source line CSL may be commonly connected to sources of the ground selection transistors GST. In addition, the ground selection line GSL, a plurality of word lines WL, and the string selection line SSL may be disposed between the common source line CSL and the bit lines BL. The ground selection line GSL may be used as a gate electrode of the ground selection transistor GST, the word lines WL may be used as gate electrodes of the memory cells MC, and the string selection line SSL may be used as a gate electrode of the string selection transistor SST.

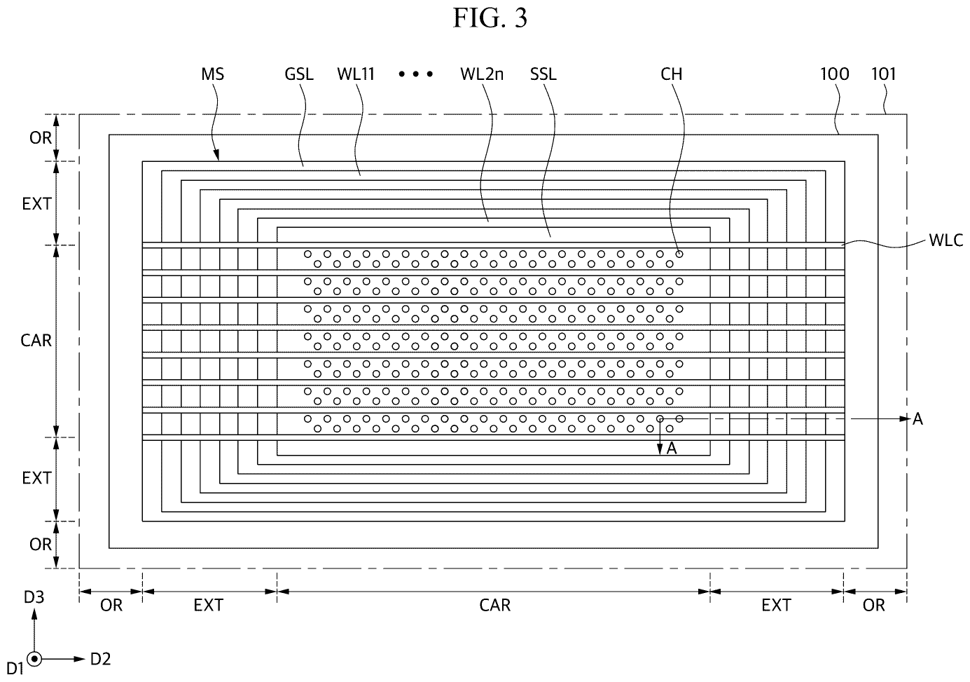

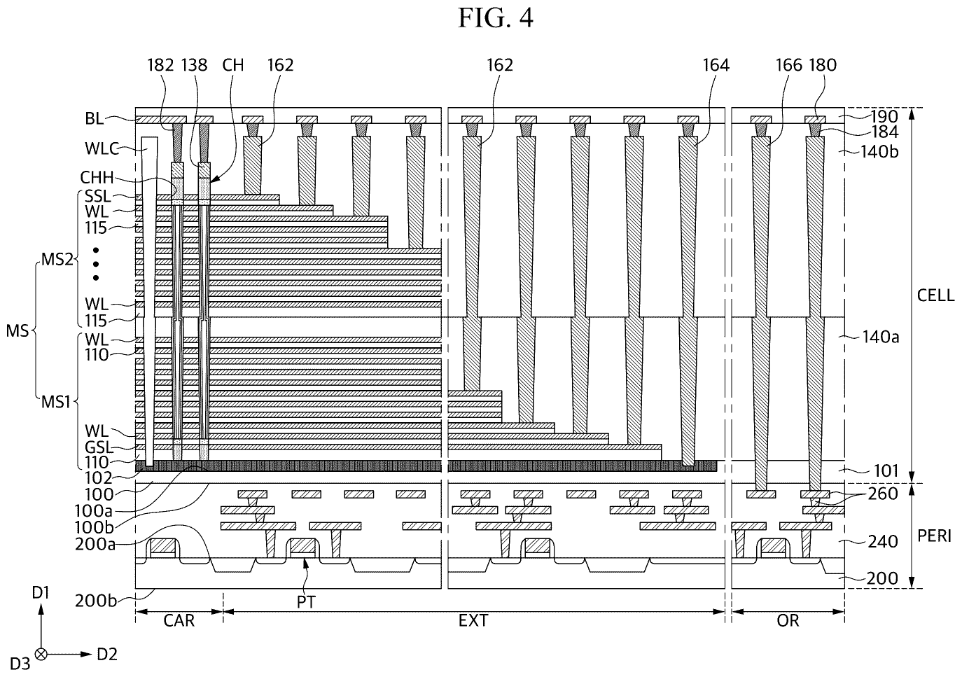

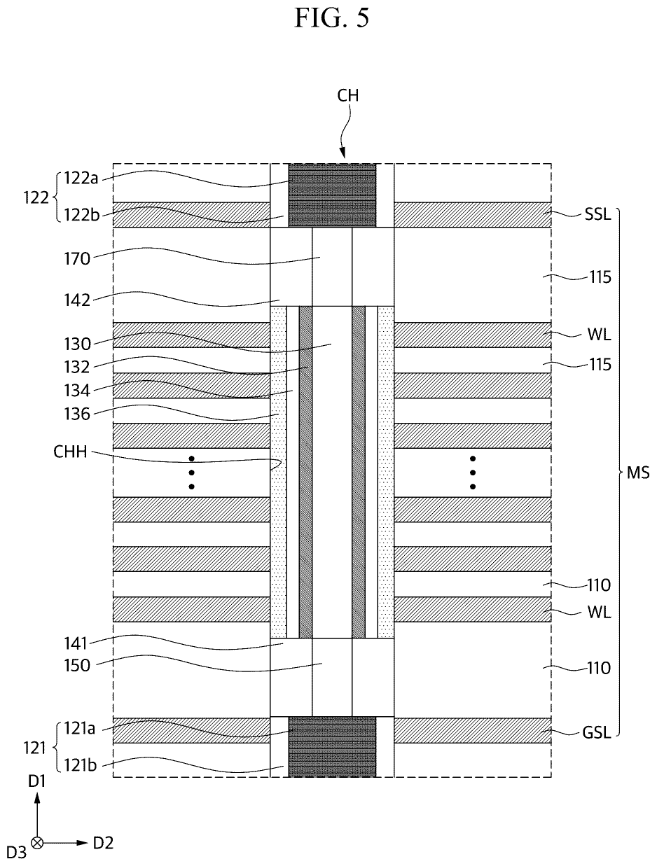

FIG. 3 is a schematic layout diagram illustrating a semiconductor memory device according to some example embodiments. FIG. 4 is an example diagram showing a cross-section taken along line A-A of FIG. 3. FIG. 5 is an example diagram illustrating a channel structure of a semiconductor memory device according to some example embodiments.

Referring to FIGS. 3 to 5, the semiconductor memory device according to some example embodiments may include a cell structure CELL and a peripheral circuit structure PERI.

According to some example embodiments, the cell structure CELL may include a cell substrate 100, an insulating substrate 101, a mold structure MS, an interlayer insulating film 140a and 140b, a channel structure CH (e.g., plurality of channel structures CH), a word line cutting line WLC, the bit line BL (e.g., plurality of bit lines BL), a gate contact 162 (e.g., plurality of gate contacts 162), and a cell wiring structure 180 (e.g., plurality of cell wiring structures 180).

According to some example embodiments, the cell substrate 100 may include or be, for example, a semiconductor substrate such as a silicon substrate, a germanium substrate, or a silicon-germanium substrate. Alternatively, the cell substrate 100 may also include or be a silicon-on-insulator (SOI) substrate or a germanium-on-insulator (GOI) substrate.

According to some example embodiments, the cell substrate 100 may include an impurity. For example, the cell substrate 100 may include an n-type impurity (for example, phosphorus (P) and arsenic (As)). However, example embodiments are not limited thereto. For example, the cell substrate 100 may also include a p-type impurity. The cell substrate 100 may include polysilicon (poly-Si) doped with the n-type impurity.

According to some example embodiments, the cell substrate 100 may include a cell array region CAR and an extension region EXT.

According to some example embodiments, a memory cell array (for example, 20 of FIG. 1) including a plurality of memory cells may be formed in the cell array region CAR. For example, the channel structures CH, the bit lines BL, and the gate electrodes GSL, WL, and SSL to be described below may be disposed in the cell array region CAR. Hereinafter, a surface of the cell substrate 100 on which the memory cell array is disposed may be referred to as a front surface 100a of the cell substrate. In contrast, a surface of the cell substrate 100 opposite to the front surface of the cell substrate 100 may be referred to as a rear surface 100b of the cell substrate.

According to some example embodiments, the extension region EXT may be disposed around the cell array region CAR. For example, the extension region EXT may surround the cell array region CAR in a plan view. The gate electrodes GSL, WL, and SSL to be described below may be stacked in a stepwise manner in the extension region EXT.

According to some example embodiments, the insulating substrate 101 may be formed around the cell substrate 100. The insulating substrate 101 may form an insulating region around the cell substrate 100. For example, the insulating substrate 101 may include, but is not limited to, at least one of silicon oxide, silicon nitride, silicon oxynitride, and silicon carbide.

According to some example embodiments, it is illustrated merely as an example that a lower surface of the insulating substrate 101 is disposed flush with a lower surface of the cell substrate 100. As another example, the lower surface of the insulating substrate 101 may also be lower than the lower surface of the cell substrate 100.

According to some example embodiments, the cell substrate 100 and the insulating substrate 101 may further include an outer region OR. The outer region OR may be disposed outside the cell array region CAR and the extension region EXT. For example, the outer region OR may surround the cell array region CAR and the extension region EXT in a plan view. A contact plug 166 to be described below may be disposed in the outer region OR.

According to some example embodiments, the mold structure MS may be formed on the front surface 100a of the cell substrate. The mold structure MS may include a plurality of gate electrodes GSL, WL, and SSL stacked on the cell substrate 100 and a plurality of mold insulating films 110 and 115. Each of the gate electrodes GSL, WL, and SSL and each of the mold insulating films 110 and 115 may have a layered structure extending in parallel with the front surface 100a of the cell substrate. The gate electrodes GSL, WL, and SSL may be spaced apart from each other by the mold insulating films 110 and 115 and stacked on the cell substrate 100 sequentially.

According to some example embodiments, the mold structure MS may include a first mold structure MS1 and a second mold structure MS2 which are stacked on the cell substrate 100 sequentially.

According to some example embodiments, the first mold structure MS1 may include first gate electrodes GSL and WL and the first mold insulating film 110 which are stacked alternately on the cell substrate 100. In some example embodiments, the first gate electrodes GSL and WL may include the ground selection line GSL and the word lines WL which are stacked on the cell substrate 100 sequentially. It is illustrated merely as an example that the first gate electrodes GSL and WL include one ground selection line GSL, but the first gate electrodes GSL and WL may also include two or more ground selection lines.

According to some example embodiments, the second mold structure MS2 may include second gate electrodes WL and SSL and the second mold insulating film 115 which are stacked alternately on the first mold structure MS1. In some example embodiments, the second gate electrodes WL and SSL may include the word lines WL and the string selection line SSL which are stacked on the first mold structure MS1 sequentially. It is illustrated merely as an example that the second gate electrodes WL and SSL include one string selection line SSL, but the second gate electrodes WL and SSL may also include two or more string selection lines. According to some example embodiments, each of the gate electrodes GSL, WL, and SSL may include or may be, but is not limited to, a conductive material, for example, metal such as tungsten (W), cobalt (Co), and nickel (Ni) or semiconductor material such as silicon.

According to some example embodiments, each of the mold insulating films 110 and 115 may include an insulating material. For example, the mold insulating films 110 and 115 may include, but are not limited to, at least one of silicon oxide, silicon nitride, and silicon oxynitride.

According to some example embodiments, the interlayer insulating film 140a and 140b may be formed on the cell substrate 100 and cover the mold structure MS. The interlayer insulating film 140a and 140b may include the first interlayer insulating film 140a and the second interlayer insulating film 140b which are stacked on the cell substrate 100 sequentially. The first interlayer insulating film 140a may cover the first mold structure MS1, and the second interlayer insulating film 140b may cover the second mold structure MS2. For example, the interlayer insulating film 140a and 140b may include, but is not limited to, at least one of silicon oxide, silicon oxynitride, and a low-permittivity (low-k) material having smaller permittivity than silicon oxide.

According to some example embodiments, the channel structures CH may be formed within the mold structure MS of the cell array region CAR. Each channel structure CH may extend in a vertical direction (for example, a first direction D1) intersecting an upper surface of the cell substrate 100 and penetrate the mold structure MS. For example, each channel structure CH may be a pillar shape (for example, a cylindrical shape) extending in the first direction D1. Accordingly, the channel structure CH may intersect each of the gate electrodes GSL, WL, and SSL. In some example embodiments, the channel structure CH may have a bent part between the first mold structure MS1 and the second mold structure MS2.

According to some example embodiments, the channel structure CH may be disposed within a channel hole CHH penetrating the mold structure MS. The channel hole CHH may penetrate the mold structure MS on the cell substrate 100. The channel structures CH may be arranged in a zigzag form. For example, the channel structures CH may be arranged to be offset between each other in the second direction D2 and the third direction D3 parallel to the upper surface of the cell substrate 100. A plurality of channel structures CH arranged in the zigzag form may improve the integration degree of the semiconductor memory device. In some example embodiments, the plurality of channel structures CH may be arranged in a honeycomb form.

According to some example embodiments, each channel structure CH may include a first transistor 121, a second transistor 122, a light emitting part 150, a light detecting part 170, a waveguide 130, an electrode layer 132, a channel layer 134, and a variable resistance layer 136.

According to some example embodiments, the first transistor 121 may be connected to the ground selection line GSL. At least a portion of a side surface of the first transistor 121 may be in contact with the ground selection line GSL. The first transistor 121 may be electrically connected to the ground selection line GSL.

According to some example embodiments, the first transistor 121 may include a first semiconductor layer 121a and a first dielectric film 121b. The first semiconductor layer 121a may be surrounded by the first dielectric film 121b. The first semiconductor layer 121a may overlap the waveguide 130 and the light emitting part 150 in the first direction D1. The first dielectric film 121b may surround the first semiconductor layer 121a. The first dielectric film 121b may be disposed on an outer sidewall of the first semiconductor layer 121a.

According to some example embodiments, the first semiconductor layer 121a may include or may be, but is not limited to, a semiconductor material such as single-crystal silicon, polycrystalline silicon, organic semiconductor material, and carbon nanostructure. As an example, the first semiconductor layer 121a may be polysilicon (poly-Si).

According to some example embodiments, the first dielectric film 121b may include or may be at least one of silicon oxide, silicon nitride, silicon oxynitride, and a high-permittivity material having greater permittivity than silicon oxide. The high-permittivity material may include, for example, at least one of aluminum oxide, hafnium oxide, lanthanum oxide, tantalum oxide, titanium oxide, lanthanum hafnium oxide, lanthanum aluminum oxide, dysprosium scandium oxide, and a combination thereof.

According to some example embodiments, the first transistor 121 may be disposed on one surface of the light emitting part 150. For example, the first transistor 121 may be disposed on one surface of the light emitting part 150 facing the cell substrate 100. In the first direction D1, the first transistor 121 may be disposed opposite the waveguide 130 based on the light emitting part 150.

According to some example embodiments, the second transistor 122 may be connected to the string selection line SSL. At least a portion of a side surface of the second transistor 122 may be in contact with the string selection line SSL. The second transistor 122 may be electrically connected to the string selection line SSL.

According to some example embodiments, the second transistor 122 may include a second semiconductor layer 122a and a second dielectric film 122b. The description of the second semiconductor layer 122a and the second dielectric film 122b are substantially identical to the description of the first semiconductor layer 121a and the first dielectric film 121b and thus omitted.

According to some example embodiments, the second transistor 122 may be disposed on one surface of the light detecting part 170. For example, the second transistor 122 may be disposed on one surface of the light detecting part 170 facing the bit line BL. In the first direction D1, the second transistor 122 may be disposed opposite the waveguide 130 based on the light detecting part 170.

According to some example embodiments, the light emitting part 150 and the light detecting part 170 may be spaced apart from each other in the first direction D1. The light emitting part 150 and the light detecting part 170 may be spaced apart with the waveguide 130 in between. The light emitting part 150 and the light detecting part 170 may be disposed to face each other in the first direction D1.

According to some example embodiments, the light emitting part 150 may be disposed on the first transistor 121. In the first direction D1, the light emitting part 150 may be disposed between the first transistor 121 and the waveguide 130. In the first direction D1, the light emitting part 150 may be disposed between the ground selection line GSL and the plurality of word lines WL. For example, in the first direction D1, based on the cell substrate 100, the height at which the light emitting part 150 is disposed may be between the height of the ground selection line GSL and the height of the plurality of word lines WL. The light emitting part 150 may emit light. The light emitting part 150 may emit light toward the light detecting part 170.

According to some example embodiments, the light emitting part 150 may be a light source or a light emitter such as a light emitting diode. The light emitting diode of the light emitting part 150 may have a PN junction structure.

According to some example embodiments, the light emitting part 150 may have a junction structure of a p-type semiconductor and an n-type semiconductor in the first direction D1. The light emitting part 150 may include a double layer including different conductive types of semiconductor materials. For example, one layer of the double layer included in the light emitting part 150 may be or include a first conductive type semiconductor material. For example, one layer of the double layer may include or be p-type silicon. One layer of the double layer may include or be silicon doped with a p-type impurity. Another layer of the double layer included in the light emitting part 150 may be or include a second conductive type semiconductor material. The other layer of the double layer may be or include silicon doped with an n-type impurity.

According to some example embodiments, the light detecting part 170 may be disposed on the second transistor 122. In the first direction D1, the light detecting part 170 may be disposed between the second transistor 122 and the waveguide 130. The light detecting part 170 may detect light. For example, the light detecting part 170 may be a light detector (e.g., photodetector), such as a photodiode or a Schottky diode. The diode included in the light detecting part 170 may have a PN junction structure. The light detecting part 170 may detect light emitted from the light emitting part 150.

According to some example embodiments, when the light emitting part 150 and the light detecting part 170 include a diode with the PN junction structure, a p-type semiconductor layer of the light emitting part 150 and an n-type semiconductor layer of the light detecting part 170 may face each other in the first direction D1.

According to some example embodiments, in the second direction D2, the width of each of the light emitting part 150 and the light detecting part 170 may be identical to the width of the waveguide 130. In the second direction D2, the width of each of the light emitting part 150 and the light detecting part 170 may be less than the width of the channel hole CHH. The light emitting part 150 and the light detecting part 170 may overlap the waveguide 130 in the first direction D1.

According to some example embodiments, the light emitting part 150 and the light detecting part 170 may be spaced apart from an inner sidewall of the channel hole CHH. The light emitting part 150 may be spaced apart from the first mold insulating film 110. The light emitting part 150 may be surrounded by a first insulating film 141.

According to some example embodiments, the first insulating film 141 may surround the light emitting part 150. The first insulating film 141 may be disposed between the light emitting part 150 and the first mold insulating film 110. The first insulating film 141 may be disposed between the first transistor 121 and the electrode layer 132, the channel layer 134, and the variable resistance layer 136 in the first direction D1.

According to some example embodiments, the light detecting part 170 may be in contact with a second insulating film 142. The light detecting part 170 may be spaced apart from the second mold insulating film 115. The light detecting part 170 may be surrounded by the second insulating film 142.

According to some example embodiments, the second insulating film 142 may surround the light detecting part 170. The second insulating film 142 may be disposed between the light detecting part 170 and the second mold insulating film 115. The second insulating film 142 may be disposed between the second transistor 122 and the electrode layer 132, the channel layer 134, and the variable resistance layer 136 in the first direction D1.

According to some example embodiments, the first insulating film 141 and the second insulating film 142 may include or be formed of, but are not limited to, at least one of silicon oxide, silicon nitride, and silicon oxynitride, for example.

According to some example embodiments, the waveguide 130 may be disposed between the light emitting part 150 and the light detecting part 170. The waveguide 130 may extend in the first direction D1. The waveguide 130 may be disposed within the channel hole CHH. The waveguide 130 may be disposed in the middle of the channel hole CHH in a plan view.

According to some example embodiments, the waveguide 130 may provide a traveling path of light emitted from the light emitting part 150. The light may pass through the waveguide 130 between the light emitting part 150 and the light detecting part 170. The light passing through the waveguide 130 may reach the light detecting part 170. The waveguide 130 may include or may be, but is not limited to, one of a metal material, a dielectric material, and an optical fiber.

According to some example embodiments, the electrode layer 132 may surround the waveguide 130. The electrode layer 132 may be disposed outside the waveguide 130 within the channel hole CHH. The electrode layer 132 may be disposed between the light emitting part 150 and the light detecting part 170. The electrode layer 132 may be disposed between the waveguide 130 and the channel layer 134.

According to some example embodiments, the electrode layer 132 may include or may be a conductive material. The electrode layer 132 may include or be a metal, metal oxide, or metal nitride. The electrode layer 132 may include aluminum (Al), copper (Cu), titanium nitride (TiN), titanium aluminum nitride (TixAlyNz), iridium (Ir), platinum (Pt), silver (Ag), gold (Au), polysilicon, tungsten (W), titanium (Ti), tantalum (Ta), tantalum nitride (TaN), tungsten nitride (WN), nickel (Ni), cobalt (Co), chrome (Cr), antimony (Sb), iron (Fe), molybdenum (Mo), palladium (Pd), tin (Sn), zirconium (Zr), zinc (Zn), iridium oxide (IrO2), and strontium zirconate oxide (StZrO3).

According to some example embodiments, the channel layer 134 may surround the electrode layer 132. The channel layer 134 may be disposed outside the electrode layer 132. The channel layer 134 may be disposed inside the variable resistance layer 136. The channel layer 134 may be disposed between the electrode layer 132 and the variable resistance layer 136.

According to some example embodiments, the channel layer 134 may include or may be, but is not limited to, a semiconductor material such as single-crystal silicon, polycrystalline silicon, organic semiconductor material, and carbon nanostructure.

According to some example embodiments, the variable resistance layer 136 may surround the channel layer 134. The variable resistance layer 136 may be disposed at a perimeter of the channel hole CHH. The variable resistance layer 136 may be connected to at least one gate electrode among the gate electrodes GSL, WL, and SSL. For example, the variable resistance layer 136 may be connected to the word line WL among the gate electrodes GSL, WL, and SSL.

According to some example embodiments, the thickness of the variable resistance layer 136 may be greater than the thickness of the channel layer 134 in the second direction D2 intersecting the first direction D1.

According to some example embodiments, the variable resistance layer 136 may include or be a material whose resistance changes depending on an electric field. The variable resistance layer 136 may include or may be a transition metal oxide. The variable resistance layer 136 may include or be phase-change materials, ferroelectric materials, or magnetic materials. For example, the variable resistance layer 136 may include or be NiO or perovskite. The perovskite may include a combination such as manganite, titanate, and zirconate. The variable resistance layer 136 may include or be a compound of two or more selected from a group consisting of Te, Se, Ge, Sb, Bi, Pb, Sn, Ag, As, S, Si, P, O, and C.

According to some example embodiments, a filament may be formed within the variable resistance layer 136. A memory cell may store digital information by a resistance change between various resistance states including a high resistance state (HRS) and a low resistance state (LRS).

In some example embodiments, the channel structure CH may further include a channel pad 138. The channel pad 138 may be formed to be connected to the second transistor 122. For example, the channel pad 138 may include, but is not limited to, polysilicon doped with impurities.

According to some example embodiments, the word line cutting line WLC may extend in the first direction D1 and cut the mold structure MS. The mold structure MS may be divided by the word line cutting line WLC and may form a plurality of memory cell blocks (for example, BLK1 to BLKn of FIG. 1). For example, the word line cutting line WLC may include, but is not limited to, at least one of silicon oxide, silicon nitride, and silicon oxynitride.

In some example embodiments, a source structure 102 may be formed on the cell substrate 100. The source structure 102 may be interposed between the cell substrate 100 and the mold structure MS. For example, the source structure 102 may extend along the upper surface of the cell substrate 100. The source structure 102 may be formed to be connected to the first transistor 121 of the channel structure CH. The source structure 102, which may be a source layer, may be provided as a common source line (for example, CSL of FIG. 2) of the semiconductor memory device. For example, the source structure 102 may include, but is not limited to, polysilicon doped with impurities or metal.

In some example embodiments, the source structure 102 may be formed as a multilayer. For example, the source structure 102 may include a plurality of source layers stacked on the cell substrate 100 sequentially. Each of the plurality of source layers may include, but is not limited to, polysilicon doped with impurities or polysilicon not doped with impurities.

Although not illustrated, a base insulating film may also be interposed between the cell substrate 100 and the source structure 102. For example, the base insulating film may include, but is not limited to, at least one of silicon oxide, silicon nitride, and silicon oxynitride.

In some example embodiments, the source structure 102 may not be formed within the extension region EXT where the insulating substrate 101 is formed. It is illustrated that an upper surface of the insulating substrate 101 is disposed to be flush with an upper surface of the source structure 102, which is merely an example though. As another example, the upper surface of the insulating substrate 101 may also be higher than the upper surface of the source structure 102.

According to some example embodiments, the bit line BL may be formed on the mold structure MS. The bit line BL may extend in the third direction D3 and intersect the word line cutting line WLC. In addition, the bit line BL may extend in the third direction D3 and be connected to the plurality of channel structures CH arranged along the third direction D3. For example, a bit line contact 182 connected to an upper portion of each of the channel structures CH may be formed within the second interlayer insulating film 140b. The bit line BL may be electrically connected to the channel structures CH through the bit line contact 182.

According to some example embodiments, the cell wiring structure 180 may be formed on the mold structure MS. For example, a first interwiring insulating film 190 may be formed on the second interlayer insulating film 140b, and the cell wiring structure 180 may be formed within the first interwiring insulating film 190. The cell wiring structure 180 may be electrically connected to the bit lines BL and the gate contacts 162. Accordingly, the cell wiring structure 180 may be electrically connected to the channel structure CH and the gate electrodes GSL, WL, and SSL. The number of layers and arrangement of the cell wiring structure 180 is illustrated as an example and not limited thereto.

According to some example embodiments, the cell wiring structure 180 may be connected to a peripheral circuit element PT through the contact plug 166. A peripheral circuit wiring structure 260 connected to the peripheral circuit element PT may be formed within a second interwiring insulating film 240. The contact plug 166 may extend in the first direction D1 and connect the cell wiring structure 180 and the peripheral circuit wiring structure 260. Accordingly, the bit line BL, each of the gate electrodes GSL, WL, and SSL, and/or the source structure 102 may be electrically connected to the peripheral circuit element PT.

According to some example embodiments, the gate contact 162 may be connected to each of the gate electrodes GSL, WL, and SSL. For example, the gate contact 162 may extend in the first direction D1 within the interlayer insulating films 140a and 140b and be connected to each of the gate electrodes GSL, WL, and SSL. In some example embodiments, the gate contact 162 may have a bent part between the first mold structure MS1 and the second mold structure MS2.

According to some example embodiments, a source contact 164 may be connected to the source structure 102. For example, the source contact 164 may extend in the first direction D1 within the interlayer insulating film 140a and 140b and be connected to the cell substrate 100. In some example embodiments, the source contact 164 may have a bent part between the first mold structure MS1 and the second mold structure MS2. The source contact 164 may electrically connect the source structure 102 and the cell wiring structure 180.

According to some example embodiments, the contact plug 166 may be disposed within the outer region OR. For example, the contact plug 166 may extend in the first direction D1 within the mold structure MS of the outer region OR. In some example embodiments, the contact plug 166 may have a bent part between the first mold structure MS1 and the second mold structure MS2. The contact plug 166 may penetrate the insulating substrate 101 and connect the cell wiring structure 180 and the peripheral circuit wiring structure 260. The contact plug 166 may be electrically separated from the cell substrate 100.

According to some example embodiments, each of the gate contact 162, the source contact 164, and the contact plug 166 may be connected to the cell wiring structure 180 on the interlayer insulating films 140a and 140b. The first interwiring insulating film 190 may be formed on the second interlayer insulating film 140b. The cell wiring structure 180 may be formed within the first interwiring insulating film 190. Each of the gate contact 162, the source contact 164, and the contact plug 166 may be connected to the cell wiring structure 180 by a contact via 184. The cell wiring structure 180 may also be connected to the bit line BL.

According to some example embodiments, the peripheral circuit structure PERI may include a peripheral circuit substrate 200, the peripheral circuit element PT, and the peripheral circuit wiring structure 260.

According to some example embodiments, the peripheral circuit substrate 200 may be disposed under the cell substrate 100. For example, the peripheral circuit substrate 200 may face the rear surface 100b of the cell substrate. For example, the peripheral circuit substrate 200 may be or may include a semiconductor substrate such as a silicon substrate, a germanium substrate, or a silicon-germanium substrate. Alternatively, the peripheral circuit substrate 200 may also include a silicon-on-insulator (SOI) substrate or a germanium-on-insulator (GOI) substrate.

According to some example embodiments, the peripheral circuit element PT may be formed on the peripheral circuit substrate 200. The peripheral circuit element PT may compose a peripheral circuit (for example, 30 of FIG. 1) that controls the operation of the semiconductor memory device. For example, the peripheral circuit element PT may include a control logic (for example, 37 of FIG. 1), a row decoder (for example, 33 of FIG. 1), and a page buffer (for example, 35 of FIG. 1). Hereinafter, a surface of the peripheral circuit substrate 200 where the peripheral circuit element PT is disposed may be referred to as a front surface 200a of the peripheral circuit substrate. In contrast, a surface of the peripheral circuit substrate 200 opposite to the front surface of the peripheral circuit substrate 200 may be referred to as a rear surface 200b of the peripheral circuit substrate.

According to some example embodiments, the peripheral circuit element PT may include, for example, a transistor, but it is not limited thereto. For example, the peripheral circuit element PT may also include various passive elements such as a capacitor, a resistor, and an inductor in addition to various active elements such as the transistor.

According to some example embodiments, the cell structure CELL may be stacked on the peripheral circuit structure PERI. For example, the cell structure CELL may be stacked on the second interwiring insulating film 240.

According to some example embodiments, the rear surface 100b of the cell substrate may face the front surface 200a of the peripheral circuit substrate. For example, the second interwiring insulating film 240 covering the peripheral circuit element PT may be formed on the front surface 200a of the peripheral circuit substrate. The cell substrate 100 and/or the insulating substrate 101 may be stacked on the second interwiring insulating film 240.

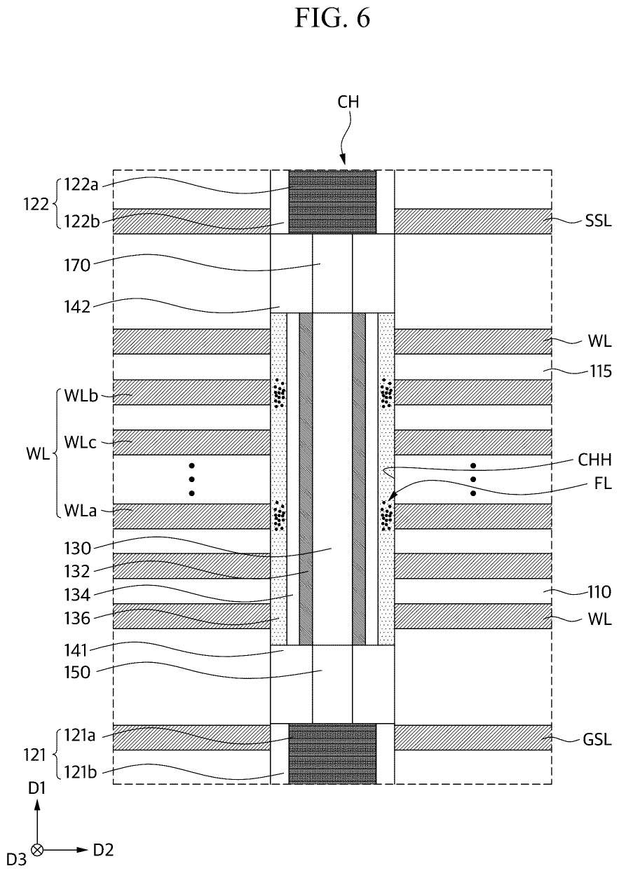

FIGS. 6 to 10 are diagrams illustrating a method of operating a semiconductor memory device according to some example embodiments. For convenience of description, differences from being described with reference to FIGS. 3 to 5 are mainly described.

Referring to FIG. 6, the plurality of word lines WL may include, for example, a first word line WLa, a second word line WLb, and a third word line WLc. In a particular memory state, a memory cell connected to the first word line WLa and the second word line WLb may be an on-cell. The variable resistance layer 136 of the memory cell connected to the first word line WLa and the second word line WLb may be in the LRS. Therefore, a filament FL may be formed within the variable resistance layer 136 connected to the first word line WLa and the second word line WLb.

According to some example embodiments, a memory cell connected to the third word line WLc may be an off-cell. The variable resistance layer 136 of the memory cell connected to the third word line WLc may be in the HRS. Therefore, the filament FL may not be formed within the variable resistance layer 136 connected to the third word line WLc.

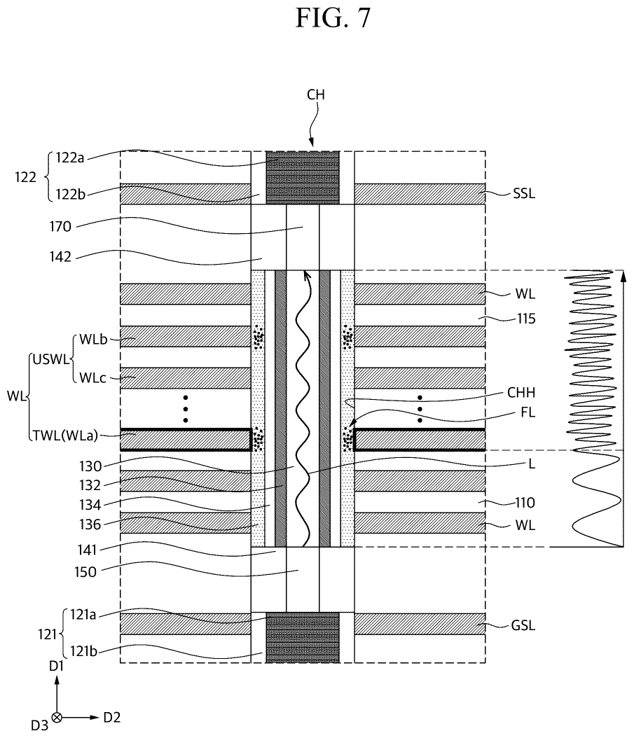

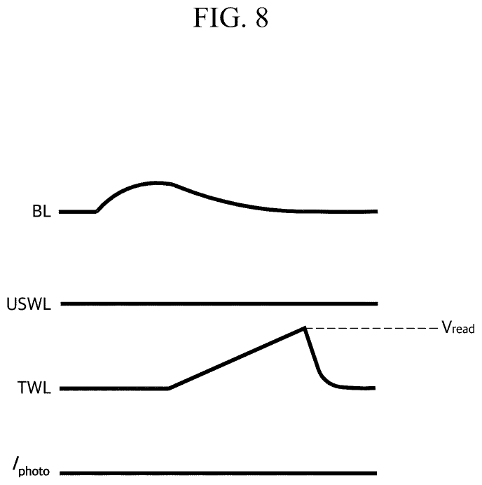

Referring to FIGS. 7 and 8, the first word line WLa may be selected as a target word line TWL. In this case, the target word line TWL may refer to a word line selected to read a memory cell connected to the target word line TWL. A read voltage Vread may be applied to the target word line TWL. Light L may be radiated inside the channel structure CH. The light L may pass through the waveguide 130 within the channel structure CH. The light L may be radiated from the light emitting part 150 toward the light detecting part 170.

According to some example embodiments, in order to read the memory cell connected to the target word line TWL, the read voltage is not applied to an unselected word line USWL that is a remaining word line excluding the target word line TWL. Therefore, a voltage state of the unselected word line USWL may be maintained to be constant.

According to some example embodiments, the properties of the light L may be changed while the light L radiated from the light emitting part 150 toward the light detecting part 170 passes through a region where the target word line TWL is disposed. For example, the wavelength of the light L may be changed.

According to some example embodiments, when the variable resistance layer 136 connected to the first word line WLa which is the target word line TWL is in the LRS and the filament FL is formed, a field such as an electric field may be formed in the channel layer 134 due to the filament FL when the read voltage Vread is applied to the target word line TWL. Therefore, the properties of the light L may be changed when the light L is radiated while passing through a peripheral portion of the first word line WLa within the waveguide 130 due to the filament FL and the field. For example, the amplitude of the light L may be changed. When the amplitude of the light L is changed, the properties such as luminance of the emitted light L may be changed and a state emitted from the light emitting part 150 may not be detected intactly in the light detecting part 170.

For example, when the light emitted from the light emitting part 150 reaches the light detecting part 170 as intact with no change in properties such as wavelength or amplitude, the luminance of the light emitted from the light emitting part 150 may be detected in the light detecting part 170. When the luminance of the light is detected in the light detecting part 170, a photocurrent Iphoto may be generated in the light detecting part 170. In contrast, when the properties are changed while the light emitted from the light emitting part 150 passes through the waveguide 130, the luminance of the light emitted from the light emitting part 150 may decrease, and thus the luminance of the light may not be detected or may detected as decreased in the light detecting part 170. When the luminance of the light is not detected or is detected as decreased in the light detecting part 170, the photocurrent Iphoto may not be generated. When the photocurrent Iphoto generated in the light detecting part 170 is not generated, a voltage drop may occur in the bit line BL. Depending on a change in the photocurrent Iphoto generated in the light detecting part 170, it may be determined whether the memory cell connected to the target word line TWL is on-cell or off-cell.

Generally, in order to read a memory cell connected to a target word line, a read voltage is also applied to remaining unselected word lines excluding the target word line. This requires high power and increases heat generation. Meanwhile, in the semiconductor memory device according to example embodiments of the present disclosure, in order to read the memory cell connected to the target word line TWL, the read voltage is applied to the target word line TWL alone and not applied to the unselected word line USWL excluding the target word line TWL, which may decrease required power and heat generation.

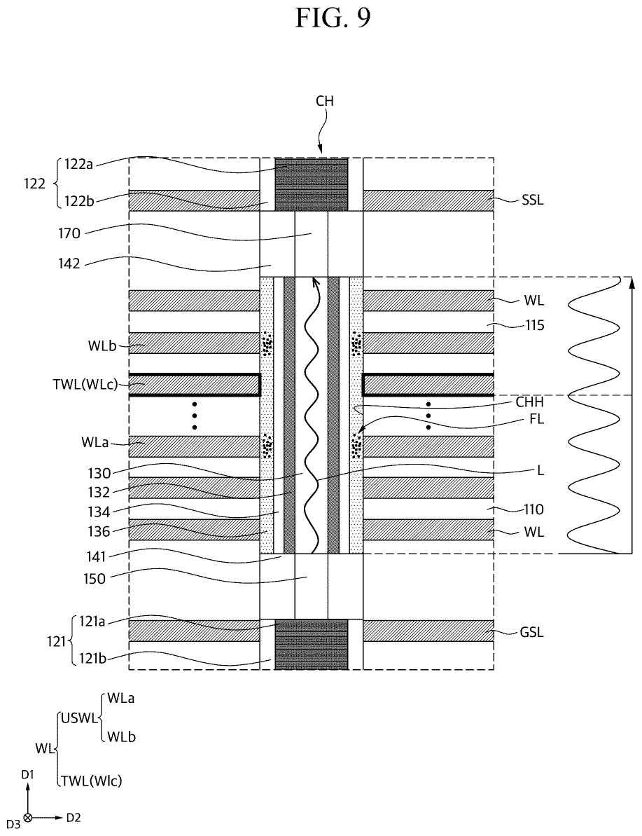

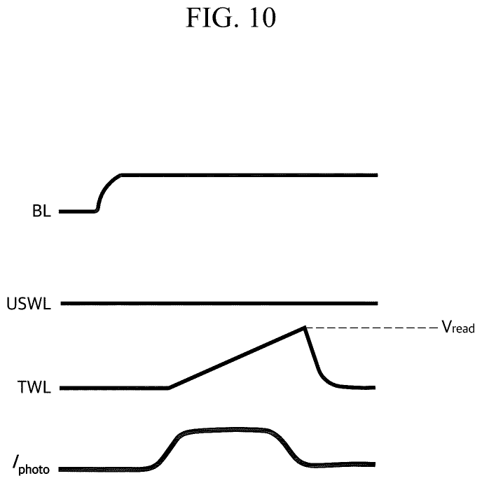

Referring to FIGS. 9 and 10, the third word line WLc may be selected as the target word line TWL. The read voltage Vread may be applied to the third word line WLc which is the target word line TWL. The read voltage Vread is not applied to the first word line WLa and the second word line WLb which are the unselected word line USWL excluding the target word line TWL.

According to some example embodiments, the properties of the light L may not be changed even though the light L irradiated from the light emitting part 150 toward the light detecting part 170 passes through a region where the target word line TWL is disposed. For example, the wavelength of the light L may be constant.

According to some example embodiments, when the variable resistance layer 136 connected to the third word line WLc which is the target word line TWL is in the HRS and the filament FL is not formed, a field such as an electric field may not be formed in the channel layer 134 even though the read voltage Vread is applied to the target word line TWL. Therefore, since no influence due to the filament FL and the field is present, the light L may not have the properties changed while passing through a peripheral portion of the third word line WLc within the waveguide 130. Further, the properties of the light L emitted from the light emitting part 150 are not changed and a state as emitted reaches the light detecting part 170 intactly, and thus the luminance of the light L may be detected in the light detecting part 170. When the luminance of the light L is detected in the light detecting part 170, the photocurrent Iphoto may be generated in the light detecting part 170. When the photocurrent Iphoto is generated in the light detecting part 170, a voltage drop may not occur in the bit line BL. Depending on a change in the photocurrent Iphoto generated in the light detecting part 170, it may be determined whether the memory cell connected to the target word line TWL is on-cell or off-cell.

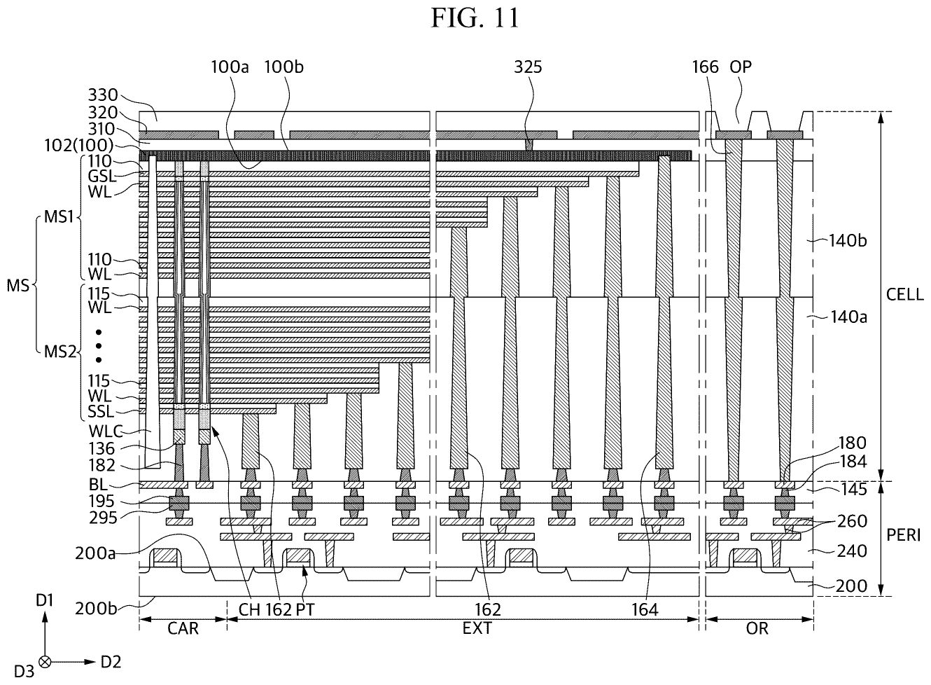

FIG. 11 is an example diagram illustrating a semiconductor memory device according to some other example embodiments. For convenience of description, differences from being described with reference to FIGS. 3 to 5 are mainly described.

Referring to FIG. 11, the source structure 102 may be the cell substrate 100. The cell substrate 100 may be the common source line (CSL of FIG. 2) of the semiconductor memory device. Hereinafter, the term of the cell substrate 100 is used for description with regard to FIG. 11.

According to some example embodiments, the front surface 100a of the cell substrate may face the peripheral circuit structure PERI. For example, the front surface 100a of the cell substrate may face the front surface 200a of the peripheral circuit substrate. The semiconductor memory device according to some example embodiments may have a chip-to-chip (C2C) structure. The C2C structure may refer to a structure in which an upper chip including the cell structure CELL is fabricated on a first wafer (for example, the cell substrate 100) and a lower chip including the peripheral circuit structure PERI is fabricated on a second wafer (for example, the peripheral circuit substrate 200) other than the first wafer, and then the upper chip and the lower chip are bonded.

According to some example embodiments, a bonding manner above may indicate a manner of electrically connecting first bonding metal 195 formed at an uppermost metal layer of the upper chip and second bonding metal 295 formed at an uppermost metal layer of the lower chip to each other. For example, when the first bonding metal 195 and the second bonding metal 295 are formed as copper (Cu), the bonding manner may be a Cu-Cu bonding manner. However, this is merely an example, and the first bonding metal 195 and the second bonding metal 295 may also be formed as other various metals such as aluminum (Al) or tungsten (W).

According to some example embodiments, as the first bonding metal 195 and the second bonding metal 295 are bonded, the cell wiring structure 180 may be connected to the peripheral circuit wiring structure 260. Accordingly, the bit line BL, each of the gate electrodes GSL, WL, and SSL, or the cell substrate 100 may be electrically connected to the peripheral circuit element PT.

According to some example embodiments, an input/output pad 320 may be disposed on the rear surface 100b of the cell substrate 100. For example, an interlayer insulating film 310 covering the cell substrate 100 may be formed on the rear surface 100b of the cell substrate 100. The input/output pad 320 may be formed on the interlayer insulating film 310. For example, the interlayer insulating film 310 may include, but is not limited to, at least one of silicon oxide, silicon oxynitride, and a low-permittivity (low-k) material having smaller permittivity than silicon oxide.

According to some example embodiments, the input/output pad 320 may be electrically connected to the cell structure CELL and/or the peripheral circuit structure PERI. For example, the contact plug 166 connecting the cell wiring structure 180 and the input/output pad 320 may be formed. For example, the contact plug 166 may extend in the first direction D1 and penetrate the interlayer insulating film 310 and the interlayer insulating film 140a and 140b.

The input/output pad 320 may be electrically connected to the cell wiring structure 180 through the contact plug 166.

According to some example embodiments, a capping insulating film 330 may be disposed on the input/output pad 320. The capping insulating film 330 may cover the input/output pad 320. The capping insulating film 330 may include a pad opening OP that exposes a portion of the input/output pad 320. The portion of the input/output pad 320 exposed by the pad opening OP may be provided as an input/output (I/O) pad.

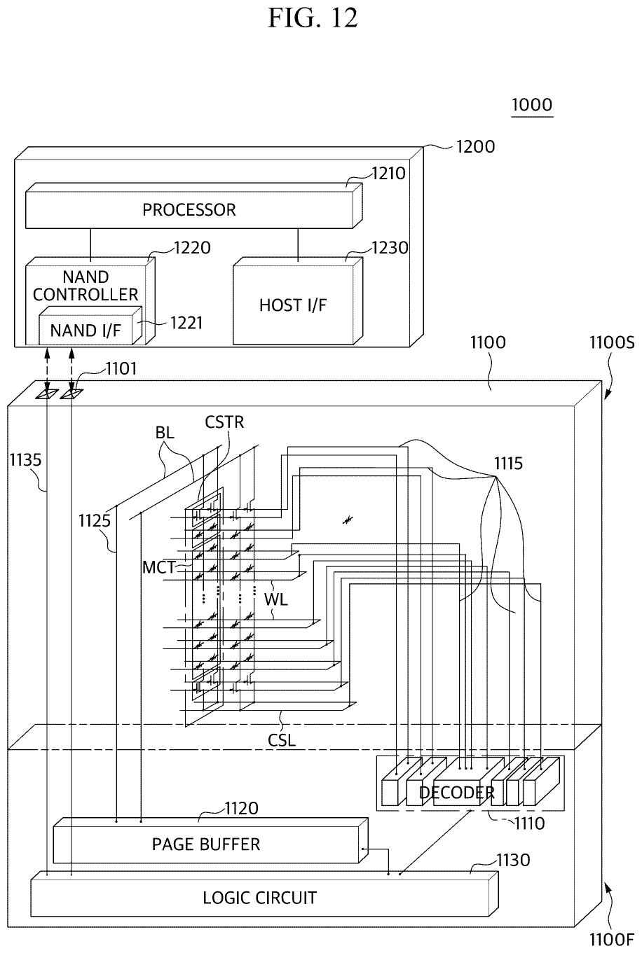

FIG. 12 is an example diagram illustrating an electronic system including a semiconductor memory device according to some example embodiments.

Referring to FIG. 12, an electronic system 1000 according to some example embodiments may include a semiconductor memory device 1100 and a controller 1200 electrically connected to the semiconductor memory device 1100. The electronic system 1000 may be a storage device including one or a plurality of semiconductor memory devices 1100 or an electronic device including the storage device. For example, the electronic system 1000 may be a solid-state drive (SSD) device, a universal serial bus (USB), a computing system, a medical device, or a communication device including one or the plurality of semiconductor memory devices 1100.

According to some example embodiments, the semiconductor memory device 1100 may be a non-volatile memory device (for example, NAND flash memory device) and, for example, the semiconductor memory device described above with reference to FIGS. 1 to 11. The semiconductor memory device 1100 may include a first structure 1100F and a second structure 1100S on the first structure 1100F.

According to some example embodiments, the first structure 1100F may be a peripheral circuit structure including a decoder circuit 1110 (for example, the row decoder 33 of FIG. 1), a page buffer 1120 (for example, the page buffer 35 of FIG. 1), and a logic circuit 1130 (for example, the control logic 37 of FIG. 1).

According to some example embodiments, the second structure 1100S may include the common source line CSL, the plurality of bit lines BL and the plurality of cell strings CSTR described above with reference to FIG. 2. The cell strings CSTR may be connected to the decoder circuit 1110 through the word line WL, at least one string selection line SSL, and at least one ground selection line GSL. In addition, the cell strings CSTR may be connected to the page buffer 1120 through the bit lines BL.

According to some example embodiments, the common source line CSL and the cell strings CSTR may be electrically connected to the decoder circuit 1110 through first connection wirings 1115 extending from the first structure 1100F to the second structure 1100S. The first connection wiring 1115 may correspond to the contact plug 166 described above with reference to FIGS. 1 to 11. The contact plug 166 may electrically connect each of the gate electrodes GSL, WL, and SSL and the decoder circuit 1110 (for example, the row decoder 33 of FIG. 1).

According to some example embodiments, the bit lines BL may be electrically connected to the page buffer 1120 through second connection wirings 1125 extending from the first structure 1100F to the second structure 1100S. The second connection wiring 1125 may correspond to the contact plug 166 described above with reference to FIGS. 1 to 11. For example, the contact plug 166 may electrically connect the bit lines BL and the page buffer 1120 (for example, the page buffer 35 of FIG. 1).

According to some example embodiments, the semiconductor memory device 1100 may communicate with the controller 1200 through an input/output pad 1101 electrically connected to the logic circuit 1130 (for example, the control logic 37 of FIG. 1). The input/output pad 1101 may be electrically connected to the logic circuit 1130 through an input/output connection wiring 1135 extending to the second structure 1100S within the first structure 1100F.

According to some example embodiments, the controller 1200 may include a processor 1210, a NAND controller 1220, and a host interface 1230. In some example embodiments, the electronic system 1000 may include the plurality of semiconductor memory devices 1100 and, in this case, the controller 1200 may control the plurality of semiconductor memory devices 1100.

According to some example embodiments, the processor 1210 may control the overall operation of the electronic system 1000 including the controller 1200. The processor 1210 may operate based on predetermined firmware and may control the NAND controller 1220 and access the semiconductor memory device 1100. The NAND controller 1220 may include a NAND interface 1221 that processes communication with the semiconductor memory device 1100. Through the NAND interface 1221, control instructions for controlling the semiconductor memory device 1100, data to be recorded in the memory cell MC of the semiconductor memory device 1100, and data to be read from the memory cell MC of the semiconductor memory device 1100 may be transmitted. The host interface 1230 may provide a communication function between the electronic system 1000 and an external host. When a control instruction is received from the external host through the host interface 1230, the processor 1210 may control the semiconductor memory device 1100 in response to the control instruction.

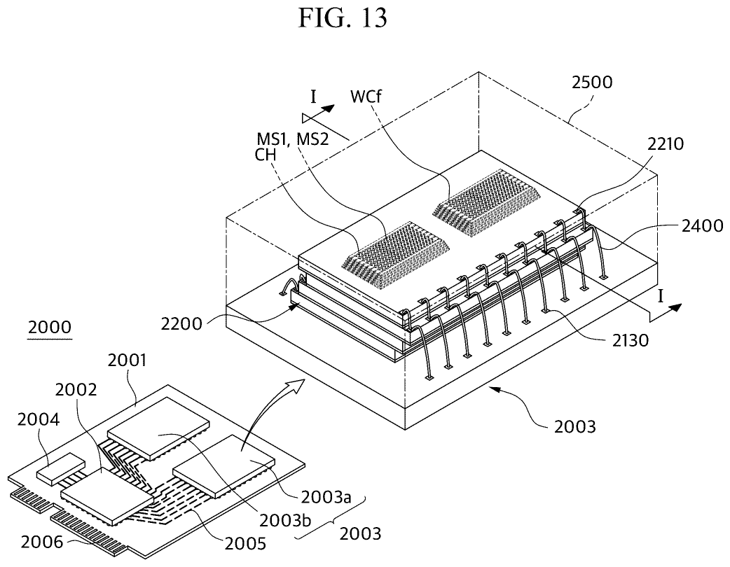

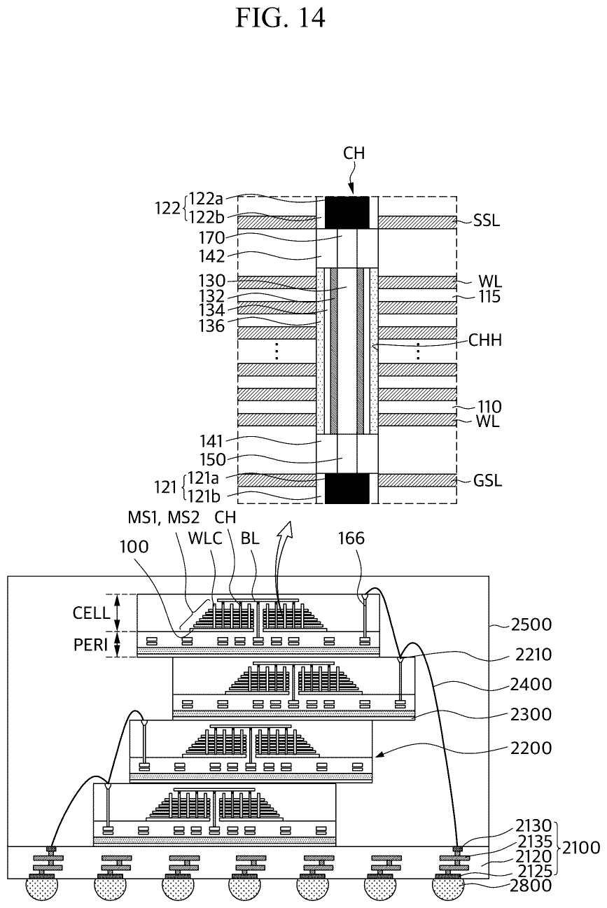

FIG. 13 is an example perspective view illustrating an electronic system including a semiconductor memory device according to some example embodiments. FIG. 14 is an example diagram showing a cross-section taken along line I-I of FIG. 13.

Referring to FIGS. 13 and 14, the electronic system according to some example embodiments may include a main substrate 2001, a main controller 2002 mounted on the main substrate 2001, one or more semiconductor packages 2003, and dynamic random access memory (DRAM) 2004. The semiconductor package 2003 and the DRAM 2004 may be mutually connected to the main controller 2002 by wiring patterns 2005 formed on the main substrate 2001.

According to some example embodiments, the main substrate 2001 may include a connector 2006 including a plurality of pins combined with an external host. The number and arrangement of the plurality of pins in the connector 2006 may vary depending on a communication interface between an electronic system 2000 and the external host. In some example embodiments, the electronic system 2000 may communicate with the external host based on any one of the interfaces such as universal serial bus (USB), peripheral component interconnect express (PCI-Express), serial advanced technology attachment (SATA), and M-Phy for universal flash storage (UFS). In some example embodiments, the electronic system 2000 may operate by power supplied from the external host through the connector 2006. The electronic system 2000 may further include a power management integrated circuit (PMIC) that distributes power supplied from the external host to the main controller 2002 and the semiconductor package 2003.

According to some example embodiments, the main controller 2002 may record data in the semiconductor package 2003 or read data from the semiconductor package 2003 and may improve the operation speed of the electronic system 2000.

According to some example embodiments, the DRAM 2004 may be buffer memory for mitigating a speed difference between the semiconductor package 2003 which is a data storage space and the external host. The DRAM 2004 included in the electronic system 2000 may operate as a kind of cache memory and may also provide a space for storing data temporarily in a control operation on the semiconductor package 2003. When the electronic system 2000 includes the DRAM 2004, the main controller 2002 may further include a DRAM controller for controlling the DRAM 2004 in addition to a NAND controller for controlling the semiconductor package 2003.

According to some example embodiments, the semiconductor package 2003 may include a first semiconductor package 2003a and a second semiconductor package 2003b spaced apart from each other. Each of the first semiconductor package 2003a and the second semiconductor package 2003b may be a semiconductor package including a plurality of semiconductor chips 2200. Each of the first semiconductor package 2003a and the second semiconductor package 2003b may include a package substrate 2100, the semiconductor chips 2200 on the package substrate 2100, a bonding layer 2300 disposed on a lower surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

According to some example embodiments, the package substrate 2100 may be a printed circuit board including package upper pads 2130. Each of the semiconductor chips 2200 may include an input/output pad 2210. The input/output pad 2210 may correspond to the input/output pad 1101 of FIG. 12.

According to some example embodiments, the connection structure 2400 may be a bonding wire electrically connecting the input/output pad 2210 and the package upper pads 2130. Accordingly, in each of the first semiconductor package 2003a and the second semiconductor package 2003b, the semiconductor chips 2200 may be electrically connected to each other in a bonding wire manner and may be electrically connected to the package upper pads 2130 of the package substrate 2100. In some example embodiments, in each of the first semiconductor package 2003a and the second semiconductor package 2003b, the semiconductor chips 2200 may also be electrically connected to each other by a connection structure including a through silicon via (TSV) instead of the connection structure 2400 with the bonding wire manner.

According to some example embodiments, the main controller 2002 and the semiconductor chips 2200 may also be included in one package. In some example embodiments, the main controller 2002 and the semiconductor chips 2200 may be mounted on a separate interposer substrate other than the main substrate 2001, and the main controller 2002 and the semiconductor chips 2200 may also be connected to each other by wiring formed on the interposer substrate.

According to some example embodiments, the package substrate 2100 may be a printed circuit board. The package substrate 2100 may include a package substrate body part 2120, the package upper pads 2130 disposed on an upper surface of the package substrate body part 2120, lower pads 2125 disposed on a lower surface of the package substrate body part 2120 or exposed through the lower surface, and internal wirings 2135 electrically connecting the upper pads 2130 and the lower pads 2125 inside the package substrate body part 2120. The upper pads 2130 may be electrically connected to the connection structures 2400. The lower pads 2125 may be connected to wiring patterns 2005 of the main substrate 2001 of the electronic system 2000 as in FIG. 13 through conductive connection parts 2800.

In the electronic system according to some example embodiments, each of the semiconductor chips 2200 may include the semiconductor memory device described above with reference to FIGS. 1 to 11. For example, the channel structure CH may include the first transistor 121, the second transistor 122, the light emitting part 150, the light detecting part 170, the waveguide 130, the electrode layer 132, the channel layer 134, and the variable resistance layer 136.

In the electronic system according to some example embodiments, when a memory cell of the semiconductor memory device of the semiconductor chips 2200 is read, a read voltage may be applied to a word line alone connected to the corresponding memory cell. The read voltage may not be applied to a word line connected to other memory cells excluding the memory cell to be read.

While various example embodiments of the present disclosure are described in detail above, the scope of the present disclosure is not limited thereto, and it will be apparent to those of ordinary skill in the art that modifications and variations may be made without departing from the scope of the present disclosure as defined by the appended claims. In addition, the aforementioned example embodiments may be implemented with some elements removed, and each example embodiment may be implemented in combination with each other.

What is claimed is:

1. A semiconductor memory device comprising:
a mold structure including a plurality of gate electrodes stacked in a first direction perpendicular to a top surface of a substrate; and
a channel structure penetrating the mold structure,
wherein the channel structure includes:
a light source configured to emit light;
a light detector spaced apart from the light source in the first direction and configured to detect light; and
a waveguide, through which the light emitted from the light source passes, disposed between the light source and the light detector.

2. The semiconductor memory device of claim 1, wherein the channel structure further includes:
an electrode layer surrounding the waveguide between the light source and the light detector;
a channel layer surrounding the electrode layer; and
a variable resistance layer surrounding the channel layer and connected to at least one gate electrode among the plurality of gate electrodes.

3. The semiconductor memory device of claim 2, wherein, in a second direction intersecting the first direction, a thickness of the variable resistance layer is greater than a thickness of the channel layer.

4. The semiconductor memory device of claim 2, configured to form a filament within the variable resistance layer.

5. The semiconductor memory device of claim 1, wherein each of the light source and the light detector has a junction structure of a p-type semiconductor and an n-type semiconductor arranged in the first direction.

6. The semiconductor memory device of claim 1, wherein the channel structure further includes:
a first transistor disposed opposite the waveguide with the light source being therebetween in the first direction; and
a second transistor disposed opposite the waveguide with the light detector being therebetween in the first direction.

7. The semiconductor memory device of claim 6, wherein the plurality of gate electrodes include at least a first string selection line, at least a first ground selection line, and a plurality of word lines disposed between the first string selection line and the first ground selection line,
wherein the first transistor is connected to the first ground selection line, and
wherein the second transistor is connected to the first string selection line.

8. The semiconductor memory device of claim 1, wherein the plurality of gate electrodes include at least a first string selection line, at least a first ground selection line, and a plurality of word lines disposed between the first string selection line and the first ground selection line, and
wherein, in the first direction, the light source is disposed between the first ground selection line and the plurality of word lines.

9. The semiconductor memory device of claim 1, wherein the plurality of gate electrodes include at least a first string selection line, at least a first ground selection line, and a plurality of word lines disposed between the first string selection line and the first ground selection line, and
wherein, in the first direction, the light detector is disposed between the first string selection line and the plurality of word lines.

10. A method of operating a semiconductor memory device, the method comprising:
selecting a target word line among a plurality of word lines that are stacked;
applying a read voltage to the target word line; and
radiating light inside a channel structure penetrating the plurality of word lines.

11. The method of claim 10, further comprising, while applying the read voltage to the target word line, applying no voltage to remaining word lines excluding the target word line among the plurality of word lines.

12. The method of claim 10, further comprising:
emitting the light from a light source of the channel structure to a light detector of the channel structure through a waveguide of the channel structure through which the light passes, the waveguide disposed between the light emitting part and the light detecting part, wherein the channel structure further comprises:
an electrode layer surrounding the waveguide;
a variable resistance layer connected to the plurality of word lines; and
a channel layer disposed between the electrode layer and the variable resistance layer.

13. The method of claim 12, wherein a property of the light changes within the waveguide.

14. The method of claim 12, further comprising detecting a current change of a current output by the light detector while the read voltage is applied to the target word line.

15. A semiconductor memory device comprising:
a mold structure including a plurality of gate electrodes stacked in a first direction perpendicular to a top surface of a substrate; and
a channel structure penetrating the mold structure,
wherein the channel structure includes:
a channel hole penetrating the mold structure;
a light emitter configured to emit light within the channel hole;
a light detector spaced apart from and facing the light emitter in the first direction and configured to detect light within the channel hole;
a waveguide, through which the light emitted from the light emitter passes, disposed between the light emitter and the light detector;
a variable resistance layer disposed along an inner sidewall of the channel hole;
an electrode layer surrounding the waveguide; and
a channel layer disposed between the electrode layer and the variable resistance layer.

16. The semiconductor memory device of claim 15, wherein the light emitter overlaps the waveguide in the first direction and does not overlap the electrode layer, the variable resistance layer, or the channel layer in the first direction.

17. The semiconductor memory device of claim 15, wherein the light detector overlaps the waveguide in the first direction and does not overlap the electrode layer, the variable resistance layer, or the channel layer in the first direction.

18. The semiconductor memory device of claim 15, wherein each of the light emitter and the light detector includes a junction diode of a p-type semiconductor and an n-type semiconductor in the first direction, and
wherein a p-type semiconductor of the light emitter and an n-type semiconductor of the light detector face each other in the first direction.

19. The semiconductor memory device of claim 15, wherein the plurality of gate electrodes include at least a first string selection line, at least a first ground selection line, and a plurality of word lines disposed between the first string selection line and the first ground selection line, and
wherein the channel structure further includes:
a first transistor disposed opposite the waveguide based on the light emitter being therebetween in the first direction, and connected to the first ground selection line; and
a second transistor disposed opposite the waveguide based on the light detector being therebetween in the first direction, and connected to the first string selection line.

20. The semiconductor memory device of claim 15, wherein, in a second direction intersecting the first direction, a width of the light emitting part and a width of the light detecting part are less than or equal to a width of the channel hole.
